(19) United States
(12) Patent Application Publication
(10) Pub. No.: US 2012/0103397 A1
(43) Pub. Date: May 3, 2012

(54) PHOTOVOLTAIC MODULE AND METHOD FOR THE PRODUCTION THEREOF

(75) Inventor: Norbert Damm, Karlsdorf-Neuthard (DE)

(73) Assignee: ROBERT BURKLE GMBH, Freudenstadt (DE)

(21) Appl. No.: 13/282,607

(22) Filed: Oct. 27, 2011

(30) Foreign Application Priority Data
Oct. 30, 2010 (DE) 10 2010 050 187.5
May 6, 2011 (EP) 11 003 759.5

(51) Int. Cl. H01L 31/048; H01L 31/18

(52) U.S. Cl. 136/251; 438/66; 257/E31.117

(57) ABSTRACT

A method for the production of a photovoltaic module, which essentially combines a transparent front substrate, such as a glass cover 1, a rear substrate, such as a rear film 6, a layer of solar cells 3 positioned therebetween, and a thermally activated softening adhesive layer 2 to form a laminar structure. For sealing the edges of the photovoltaic module, a linear body 7 framing at the edges and surrounding the layer of solar cells 3 having a thermally activated adhesive material 9 is placed between the front substrate 1 and the rear substrate 6, with the thermally activated adhesive material 9 of the linear body 7 being selected such that it does not soften or softens slower and/or at higher temperatures compared to the thermally activated adhesive layer 2 or has a higher viscosity in reference to the thermally activated adhesive layer 2. A photovoltaic module is also provided.

### CROSS-REFERENCE TO RELATED APPLICATIONS

This application claims the benefit of German Patent Application No. 10 2010 050 187.5, filed Oct. 30, 2010, as well as European Patent Application No. EP 11 003 759.5, filed May 6, 2011, both of which are incorporated herein by reference as if fully set forth.

### BACKGROUND

The invention relates to a method for the production of a photovoltaic module as well as a photovoltaic module. The photovoltaic module according to the present type is essentially comprised of a transparent front substrate, a rear substrate, an interposed layer of solar cells, and a thermally activated and thereby softening adhesive layer to form a laminar structure.

The layer of solar cells, located between the front substrate, particularly a glass cover, and the rear substrate, for example a rear film or a rear glass, may represent a thin-layer of solar cells or a layer comprising a layer of a multitude of adjacently arranged and connected together multi-crystalline, poly-crystalline, or mono-crystalline solar cells. Additionally, a thermally activated adhesive layer is provided between the front substrate and the rear substrate, for example in the form of two adhesive films arranged above and below the layer of solar cells, inserted between the front substrate and the rear substrate. These adhesive films generally comprise a transparent, thermally activated adhesive substance, such as ethylene vinyl acetate (EVA) or a transparent thermoplastic material.

Through laminating the layered stack, comprising the front substrate, the layer of solar cells, the adhesive layer, and the rear substrate under the influence of pressure and heat, a laminar structure develops due to the activation of the adhesive layer, which essentially represents the finished photovoltaic module. After the lamination, the layer of solar cells is embedded in a clear, three-dimensionally cross-linked or cured plastic layer, which cannot be separated any more by melting. Using this plastic layer, additionally the front substrate and the rear substrate are connected to each other in a fixed manner, and the solar cells including their circuitry are fixed therebetween and/or therein. This laminar structure ensures that during normal outdoor use of the photovoltaic modules over the entire course of the year there is no risk to expect on the long run that the layer of solar cells comes into contact with the environmental humidity and the oxygen of the air and thus becomes damaged.

Photovoltaic modules with a front substrate, a layer of solar cells, and a rear substrate are usually laminated in a laminating press, where they are brought into a chamber which is air-tight when the press is closed, heated via heating plates or the like, and impinged with the pressure necessary for lamination via a flexible diaphragm, which horizontally divides the chamber. For this purpose, the chamber is generally evacuated in order to avoid air pockets in the adhesive layer, which softens during the lamination process, as well as removing potentially developing processing gas and enclosed air from the interior of the layered stack before the adhesive layer is cross-linked and/or cured. An example for such a method is found in DE 10 2007 025 380 A1.

The actual lamination process lasts for a certain period of time, until the interlacing and/or curing of the adhesive layer is concluded and thus any introduction of heat into the adhesive layer as well as usually also any load upon the laminar structure is no longer required. The period of time depends on the materials used and thus it cannot be shortened by process technology. Consequently, the laminating process represents the processing step in the production of photovoltaic modules which limits the speed of the entire arrangement. Therefore it has been suggested in DE 10 2007 025 380 A1 to embody the laminating press, in which the photovoltaic modules are laminated, in several layers so that several photovoltaic modules can simultaneously be laminated in several press layers.

Another approach for accelerating the production of photovoltaic modules of the present type is disclosed in EP 1 997 614 A2. Here, the layered stacks are first preliminarily laminated in a conventional vacuum-lamination press. For this purpose, they are subjected to a vacuum in order to avoid the formation of bubbles, impinged with a compression force, and then heated until the adhesive layer has been activated to such an extent that the removal of gaseous components is concluded or has come to a halt by the activation of the adhesive layer, inversely however any penetration of air from the outside into the layers of the photovoltaic module is excluded even under normal pressure. At this point of time, the vacuum lamination press is ventilated and opened. The photovoltaic modules only preliminarily laminated here are then moved into a second lamination press (without a vacuum), in order to insert additional heat into the laminar structure under load until the interlacing of the adhesive layer and/or the curing has been concluded. According to prior art, the lamination process is therefore divided into two partial processes and/or work cycles so that the capacity of the lamination press and thus the overall arrangement is doubled for the production of photovoltaic modules.

The adhesive materials used for laminating photovoltaic modules generally show highly adhesive features as soon as they are activated. This particularly applies to the softened but not yet cross-linked and/or cured state. Due to the fact that the lamination occurs not only by the introduction of heat into the laminar structure but also by the effect of a load upon the laminar structure there is always the risk that material of the softened adhesive layer seeps out at the edges between the front substrate, for example a glass cover, and the rear substrate, particularly a rear film, thus is more or less squeezed out laterally between these layers. This material is highly adhesive, as already mentioned, resulting in tenacious contaminations of the lamination press and here particularly the flexible diaphragm or a conveyer belt used. Such contaminations not only limit the life of the soiled parts but can also potentially lead to the production of waste in the subsequently processed photovoltaic modules.

This problem is particularly relevant for the above-described short-cycle method, which is disclosed in EP 1 997 614 A2. Because here the preliminarily laminated photovoltaic modules are transported, with their adhesive layers softened up to a liquid state, from the first lamination station to the second lamination station so that any adhesive perhaps laterally seeping out of the module in the first station may also cause problems during transportation as well as in the second lamination station.

### SUMMARY

The present invention is therefore based on the objective of providing a method for producing a photovoltaic module of the type mentioned at the outset as well as to provide a photovoltaic module produced by this method in which the risk is at least considerably reduced that during the lamination process unintentional seepage of material of the thermally activated adhesive layer occurs at the edges between the front substrate and the rear substrate.

This objective is attained in a method having the features of the invention, as well as by a photovoltaic module or modules according to the invention. Advantageous embodiments of the method according to the invention as well as preferred embodiments of the photovoltaic module according to the invention are described in detail below and in the claims.

According to the present invention the photovoltaic module is therefore provided with an edge seal, which is formed by a linear body framing the edge surrounding the layer of solar cells between the front substrate and the rear substrate. This linear body forms, as mentioned above, an edge seal and thus a barrier against a lateral discharge of the softened and perhaps even liquefied adhesive layer during the lamination process. In order for the linear body to cause such a barrier effect, it also comprises at least partially a thermally activated adhesive material so that it bonds during lamination both with the front substrate on the one side as well as with the rear substrate on the other side and thus reliably prevents discharge of material of the thermally activated adhesive layer from the interior of the laminar structure to the outside. Simultaneously it is ensured according to the invention that the thermally activated adhesive material of the linear body either does not soften or, in reference to the thermally activated adhesive layer, softens slower and/or only at higher temperatures, or that at the same temperature the thermally activated adhesive material of the linear body in reference to the thermally activated adhesive layer has a higher viscosity. Even if the actual thermally activated adhesive layer of the photovoltaic module enters a very soft or even a liquid state, the barrier effect of the surrounding linear body is ensured due to its very low softening or due to its higher viscosity.

In order to optimally attain both requirements of the linear body, i.e. a high adhesive effect towards the front substrate on the one side and the rear substrate on the other side and yet to ensure a higher stability by a lower softening or higher viscosity than the thermally activated adhesive layer and thus create the barrier effect, in a preferred further development of the present invention the linear body may compose a core and a jacket layer covering it, made from a thermally activated adhesive material. The core is then responsible for stability and the barrier effect related thereto, while the jacket layer may be provided with a particularly high and early activated adhesive effect. For example, the jacket layer may comprise a polyisobutyl-material or an epoxy resin. The core may comprise an extruded, low-elasticity material, for example, such as a thermally stable plastic or a metal, particularly copper, aluminum, or tin.

This preferred further development of the present invention eliminates particularly a specific problem of photovoltaic modules provided with a glass cover and a rear glass as the front substrate and the rear substrate, particularly when thin glass plates are used: experiments of the applicant have shown that different temperature ranges of the softening of conventional edge seals and conventional adhesive layers may lead to problems during the lamination of photovoltaic modules with glass covers and rear glass, particularly when the lamination occurs advantageously under the effects of pressure and heat, namely preferably in a diaphragm press. Because the elastically deforming diaphragm of a diaphragm press, applying the planar load upon the photovoltaic module required for lamination by utilizing a pressure difference between an evacuated processing chamber and the ambient atmospheric pressure, closely contacts during lamination the contour of the photovoltaic module, in particular also at the edge areas of the glass plates, so that the upper glass plate, due to higher compression, is deformed and bent at the edges. Here, particularly a central bulging develops of the upper glass plate while simultaneously the two glass plates of the photovoltaic module are further compressed at the edges than specified for the target dimension of the module.

This bulging of the upper glass plate, which was difficult to avoid in prior art, creates a pressure release in the interior area of the photovoltaic module so that here processing gas accumulates and may lead to larger, lasting, and very undesirable gas bubbles. Further, the corner and edge areas of the photovoltaic module compressed during the lamination process below target dimensions relax after the end of the compression, thus the upper glass plate returns at least partially into its planar original form. If this occurs in the still heated state of a freshly laminated photovoltaic module this also leads to a pressure release in the adhesive layer, here at the edges, as well as in the edge sealing material allowing processing gas that was kept dissolved during the lamination process under the existing compression, to form extremely disadvantageous edge and corner bubbles.

If for the production of photovoltaic modules much thinner glass plates are used than in the past, which is very desirable with regards to production costs, in the prior art there is further the risk of broken glass. Even if these thin glass plates remain intact, additional difficulties develop by their increased ability for deformation: By the compression of the glass cover and the rear glass in the corner and edge areas a force develops upon the solar cells positioned therebetween and acting within the modular level, which leads in the softened adhesive layer to a lateral movement of the individual cells and to an off-set thereof, which in the worst case scenario can lead to a short-circuit of the solar cell circuitry.

The above-stated specific problem of conventional glass-glass modules is addressed in the use of a linear body as an edge seal of a photovoltaic module with a rear glass and a glass cover, preferred within the scope of the present invention, with the linear body comprising a mechanically low-elasticity core as well as a thermally activated adhesive cover layer or jacket layer.

For the core of the linear body, a material is preferably used according to the invention with its elasticity, upon softening of the thermally activated adhesive layer of the photovoltaic module during the lamination process, being lower than the elasticity of the softened adhesive layer. This elasticity may exhibit a (low) elasticity of a low elasticity solid body, however it may also be based on the viscosity of the core material, which then during the lamination process of the photovoltaic module is significantly higher than the viscosity of the thermally activated adhesive layer softening during the lamination process. The lamination process offers the chance to use a melting adhesive as the core of the linear body according to the invention, which softens slower compared to the thermally activated adhesive layer of the module or only at a higher temperature.

The relative arrangement of the low elasticity core according to the invention and the thermally activated adhesive edge or jacket layer of the linear body according to the invention in reference to each other can be selected very differently, depending on the purpose for use.

For example, the core of the linear body according to the invention may be provided with a covering jacket layer so that a prefabricated linear body is given, which can be provided during the production of the photovoltaic module for example as a tape material on a roll or by a robot controlled, heated extruder head. In order to implement the method according to the invention it can be applied onto the bottom substrate during the placement of the layers of the module, surrounding the layer of solar cells and the thermally activated adhesive layer, upon which subsequently the substrate is placed, located on top during lamination.

The core of the linear body according to the invention may also comprise only a thermally activated adhesive edge layer in those areas that come into contact with the substrates, particularly glass plates of the photovoltaic module. This beneficially occurs by applying the adhesive edge layer directly upon the front substrate and/or upon the rear substrate, while the core of the linear body is then located between these two edge layers when the substrate located on top during lamination is placed upon the other layers of the module.

Finally, the scope of the invention also includes arranging the core and the edge layer of the linear body according to the invention side-by-side, seen in the modular level, with the edge layer optionally being located radially outwardly and/or radially inwardly within the core, and completely filling the space between the two substrates of the module.

In photovoltaic modules with two glass plates as front and rear substrates it has proven beneficial in all cases for the thickness of the low elasticity core of the linear body according to the invention to be approximately equivalent to the clear space between the two glass plates at the target distance. The cross-sectional shape of the core of the linear body may vary here; it may be rectangular, round, oval, V-shaped, or be present in any other form. The thickness of the entire linear body according to the invention, i.e. the material comprised from the core and the edge layer and/or jacket layer, preferably amounts to approximately 1.2 times the thickness of the core per se. This means that a jacket layer comprises approximately 10% of the thickness of the core, or an edge layer radially applied adjacent to the core has a thickness 1.2 times the thickness of the core. This ensures that by a softening of the jacket or edge layer during lamination sufficient material is provided to lastingly seal the contact area between the core and the glass cover and/or the rear glass in a gas or moisture tight fashion.

Another preferred embodiment of the present invention comprises that the same material is used for the linear body as the thermally activated adhesive material which also represents the thermally activated adhesive layer of the laminar structure. In order to achieve the differences according to the invention between the linear body sealing the edges and the interior adhesive layer, said adhesive material may be provided with additives influencing its activation, the adhesive effect, and/or the viscosity of the material. This can be implemented particularly well in thermoplastic elastomers, with their viscosity being altered in a targeted fashion by additives. However, other materials can also be used in this manner for the adhesive layer, such as EVA, TPO, TPU, PVB, and ionomers, in addition to the linear body according to the present invention. In addition to the advantages of the chemical tolerance of the adhesive layer and the same weather-resistant features here additionally the advantage develops that the linear body for sealing the edges is also transparent, similar to the actual adhesive layer, thus invisible in the finished photovoltaic module, on the one hand, and not interfering with the light irradiation into the photovoltaic module, on the other hand.

In order to implement the differences according to the invention between the linear body and the adhesive layer located inside without the use of any additives for the thermally activated adhesive layer and the thermally activated adhesive material of the linear body, it may be alternatively provided within the scope of the present invention to use the material of the thermally activated adhesive layer with a higher layer thickness than the thermally activated adhesive layer. Here, this higher layer thickness shall be equivalent to 1.1 times to 3 times, preferably 1.2 times to 1.5 times the layer thickness of the interior adhesive layer. Due to the accumulation of material at the edges the desired barrier effect develops with a suitable adhesive material, because the thickened material softens slower and, if the processing parameters are selected appropriately, has a higher viscosity than the interior adhesive layer.

Within the scope of the present invention other materials can also be used for the linear body according to the invention, of course, such as ionomer-barrier materials, PU-hotmelt, materials based on TPS and PN (polyisobutylene), foamed thermoplastic elastomers, and the like.

Photovoltaic modules according to the invention preferably have a glass cover as the front substrate and a rear film as the rear substrate. However, the present invention is not limited thereto; rather it also comprises photovoltaic modules and methods for the production thereof which comprise a glass cover and a rear film or are designed with a transparent cover film and a rear film. Thus, the invention is suitable for all known types of photovoltaic modules: glass-glass modules, glass-film modules, and film-film modules. Other substrate combinations are also possible and included in the present invention, for example a module with a cover film and a rear glass, or a module with a rear plate not made from glass and a glass cover or a cover film.

### BRIEF DESCRIPTION OF THE DRAWINGS

In the following, an exemplary embodiment for a method according to the invention to produce a photovoltaic module is described and explained using the attached drawings. Shown are:

FIG. 1 is a schematic cross-sectional view through a photovoltaic module with a glass cover and a rear film in a first assembly phase;

FIG. 2 is a cross-sectional view of FIG. 1 in a second assembly phase;

FIG. 3 is a schematic cross-sectional view through a photovoltaic module with a glass cover and a rear glass according to a second exemplary embodiment, in a first assembly phase;

FIG. 4 is a cross-sectional view of FIG. 3 in a second assembly phase;

FIG. 5 is a schematic cross-sectional view of a finished laminated photovoltaic module according to a third exemplary embodiment;

FIG. 6 is a schematic cross-sectional view of a finished laminated photovoltaic module according to a fourth exemplary embodiment.

### DETAILED DESCRIPTION OF THE PREFERRED EMBODIMENTS

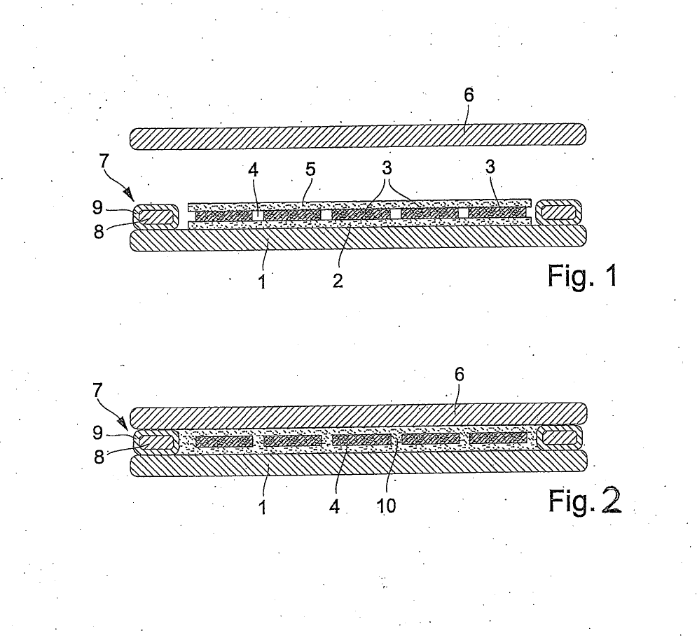

FIG. 1 shows a first and FIG. 2 a second phase of the production of a photovoltaic module and particularly the production of a first embodiment of an edge seal according to the invention in schematic cross-sections. In FIG. 1, a glass cover 1 was placed upon a support table (not shown) and a first thermally activated adhesive layer 2 was applied thereon in the form of an EVA-film. Then a number of solar cells 3 were placed upon this first adhesive layer 2 and electrically interconnected via soldered connectors (not shown) in order to form a layer of solar cells 4. Finally, a second EVA-film was placed upon this layer of solar cells 4 as a second adhesive layer 5.

Before a rear film 6 is placed upon the layer of solar cells 4 and/or the second adhesive layer 5, according to the invention a linear body 7 is placed around the layer of solar cells 4 and the two adhesive layers 2, 5 circumferentially on the edge area of the glass cover 1, with this linear body 7 here comprising an interior core 8, which exhibits low mechanical elasticity, and a jacket layer 9 surrounding the core 8. The jacket layer 9 comprises a thermally activated, adhesive material which is viscous under the influence of heat.

FIG. 2 shows the finished laminated photovoltaic module, comprising the glass cover 1, a layer of solar cells 4 embedded in a transparent and cross-linked adhesive layer 10, the rear film 6, and the edge seal formed by the linear body 7 with the core 9 and the jacket layer 9. The core 8 of the linear body 7 comprises a hot adhesive, with its rheological features being such that during the thermal processing phases of the lamination a constantly higher viscosity is given than in the adhesive layers 2, 5. The jacket layer 9 of the linear body 7 comprises isobutyl.

In an experiment with the photovoltaic modules shown in FIGS. 1 and 2 using the processing steps shown, during the lamination process or thereafter no relevant discharge of adhesive material could be detected from the edges of the photovoltaic modules. Any adverse contamination of the lamination press and/or the conveyer installations with adhesive substances could therefore be effectively prevented.

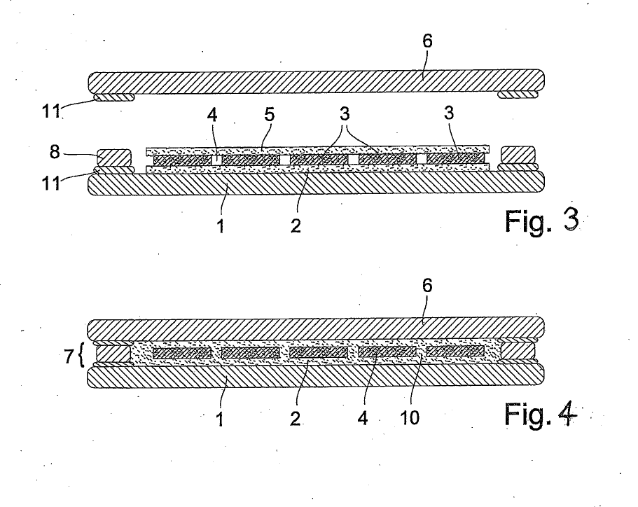

Exemplary embodiments for PV-modules with glass covers and rear glass, thus glass-glass modules, are shown in FIGS. 3 through 6.

The exemplary embodiment visualized in FIGS. 3 and 4 of a method according to the invention for the production of an edge seal of photovoltaic modules differs from the one shown in FIGS. 1 and 2, in addition to the material of the rear substrate, by the embodiment of the linear body 7: It is produced by applying two edge layers 11 onto the interior edges of the glass cover 1 and the rear glass 6 as well as by a separate placement of the core 8 onto the edge layer 11 located on the glass cover 1. After the placement of the rear glass 6 a three-layered embodiment of the edge seal develops, comprising the core 8 enclosed between the two edge layers 11. After the lamination (FIG. 4) the linear body 7 has formed from these three layers, which no longer shows any difference in its features in reference to the exemplary embodiment of FIG. 2. For the rest, here it is easily discernible that the core 8 of the linear body 7, of low elasticity according to the invention, represents a reliable barrier against adhesive material seeping out of the softened adhesive layers 2, 5.

After cooling and during the operation of the photovoltaic module the linear body 7 forms the intended barrier against moisture and oxygen from the environmental air entering the interior of the photovoltaic module. Here, the two edge layers 11 ensure a fixed and lasting connection between the core 8 and the glass cover 1 as well as the rear glass 6.

FIG. 4 shows the finished laminated photovoltaic module, comprising the glass cover 1, the layer of solar cells 4 embedded in a transparent and cross-linked adhesive layer 10, the rear glass 6, and the linear body 7 with the core 8 and the jacket layer 9 forming the edge seal. Using this illustration, it is discernible that the mechanically low elasticity core 8 of the edge sealing linear body 7, which in the original state has a thickness approximately 1.2 times the target distance between the glass cover 1 and the rear glass 6 of the finished photovoltaic module, reliable prevents any compression of the edge areas of the photovoltaic module and thus any bulging of the rear glass 6 during the lamination process such that due to its mechanic stiffness an equivalent counter pressure is applied against the lamination pressure acting from above onto the module as the initially not softened adhesive layers 2, 5 in cooperation with the layer of solar cells 4. The fact that the jacket layer 9 of the laminar body 7 becomes viscous even before the adhesive layers 2, 5 become able to flow has no negative influences on the lamination process. To the contrary: For example, the contact areas between the core 8 and the glass plates 1, 6 are reliably and lastingly sealed from the penetration of moisture and oxygen.

The method according to the invention described in the exemplary embodiment shown in FIGS. 3 and 4 was performed in an experiment with glass plates, with their thickness only amounting to approximately 2 mm, and thus only half the previously common thicknesses. Even the thicknesses of EVA-films as first and second adhesive layers 2, 5 were reduced in reference to prior art by approximately 30%, in each case allowing enormous savings potentials. The core 8 of the linear body 7 comprised a hot-melt adhesive, with its rheological features being such that here during the thermal processing phases of the lamination a constantly higher viscosity was given than in the adhesive layers 2, 5. This higher viscosity was higher such that during the lamination processes no relevant corner or edge bending of the glass plates 1, 6 could develop. A difference between the thickness of the photovoltaic module at its exterior edge and the thickness of the interior area (bulging of the rear glass 6) rather amounted to less than 1/10 mm. The jacket layer 9 of the linear body 7 was made from isobutyl.

As already mentioned, the thickness of the linear body 7 amounted to 1.2 times the thickness of the layer of solar cells 4 with the surrounding adhesive layer 10 in the finished laminated state. Any relevant discharge of adhesive material from the edges of the photovoltaic module during the lamination process or thereafter was not detected. An adverse contamination with adhesive substances of the lamination press and/or the conveyer arrangements could also be prevented.

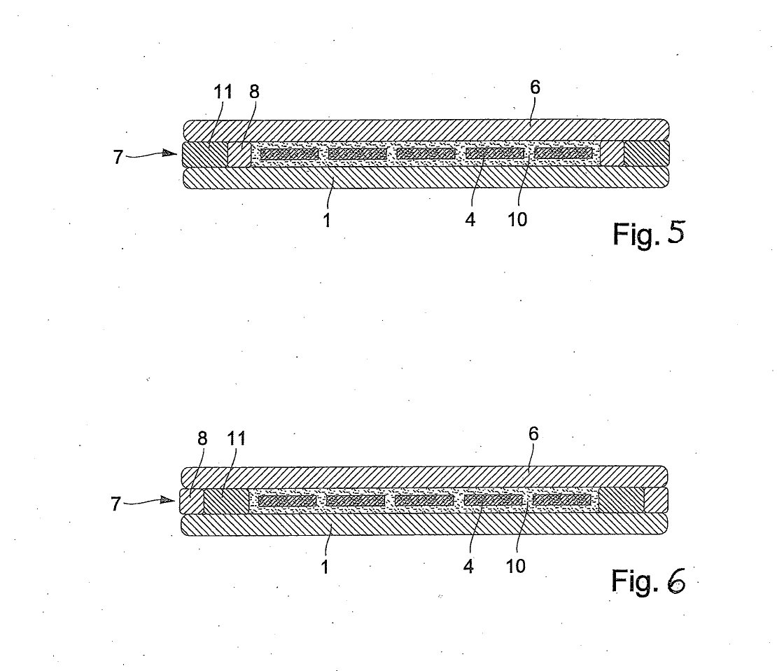

FIGS. 5 and 6 respectively show a schematic cross-section of a finished laminated photovoltaic module, as already the case in FIGS. 2 and 4. The photovoltaic modules shown in FIGS. 5 and 6 differ from the previous ones, particularly by the embodiment of a linear body 7.

Here, it respectively comprises the core 8, surrounding the photovoltaic module in the edge area, and a contacting edge layer 11 made from a thermally activated adhesive material, located in the level of the module radially outside (FIG. 5) and/or radially inside (FIG. 6), adjacent to the core 8. The core 8 in turn is embodied of the same thickness as the adhesive layer 10 with the layer of solar cells 4 embedded therein, while the edge layer 11 in its initial state was embodied approximately 20% thicker. By the melting during the lamination process the thickness reduced, and this ensured that the edge layer 11 bonded at both sides with the front substrate 1 and the rear substrate 6 in a lasting and gas and moisture tight fashion.

1.-8. (canceled)

9. A method for the production of an edge sealing of photovoltaic modules which comprise a glass cover plate (1), a rear glass plate (6), a layer of solar cells (4) arranged between the glass plates (1, 6), and at least one adhesive layer (2, 5), located between the glass plates (1, 6) and thermally activated, forming a laminar structure (1, 10, 4, 6), the method comprising: for an edge sealing of the photovoltaic module, inserting a laminar body (7) with a core (8) and a thermally activated adhesive edge layer (11) or a jacket layer (9) between the glass cover (1) and the rear glass (6), framing the edges, with a material being used for the core (8) of the linear body (7) having an elasticity during softening of the thermally activated adhesive layer (2, 5) in the lamination process of the photovoltaic module that is lower than an elasticity of the adhesive layer (2, 5) softening thereby.

10. A method according to claim 9, wherein the material used for the core (8) of the linear body (7) has a viscosity during the lamination process of the photovoltaic module that is higher than a viscosity of the thermally activated adhesive layer (2, 5).

11. A method according to claim 9, wherein an extruded material is used for the core (8) of the linear body (7) comprising a temperature stable plastic or a metal.

12. A method according to claim 9, wherein the linear body (7) is used with the core (8) and the jacket layer (9) covering it, and the linear body (7) is placed between the rear glass (6) and the glass cover (1) before the photovoltaic module is laminated.

13. A method according to claim 9, wherein the core (8) and the edge layer (11) of the linear body (7), which is embodied thicker in reference to the core (8), is arranged between the rear glass (6) and the glass cover (1), side-by-side in a plane of the photovoltaic module, before the photovoltaic modules is laminated.

14. A method according to claim 9, wherein the linear body (7) is produced with the thermally activated adhesive edge layer (11) applied on each of the rear glass (6) and the glass cover (1), and the core (8) is inserted between the two edge layers (11) before the photovoltaic module is laminated.

15. A method according to claim 9, wherein the linear body (7) is used having the core (8), with a thickness thereof being approximately equivalent to a target thickness of the finished photovoltaic module minus a thickness of the rear glass (6) and the glass cover (1).

16. A method according to claim 15, wherein the linear body (7) is used having a total thickness equivalent to 1.2 times a thickness of the core (8).

17. A method according to claim 9, wherein the linear body (7) is used, with the edge layer (11) or the jacket layer (9) being formed from a polyisobutyl material or an epoxy resin.

18. A method according to claim 17, wherein the linear body (7) is used, with the core (8) comprising a hot-melt adhesive.

19. A method according to claim 9, wherein the linear body (7) is used comprising a material transparent in the finished laminated state.

20. (canceled)

21. A photovoltaic module, comprising: a transparent front substrate (1), a rear substrate (6), a layer of solar cells (3) positioned therebetween, and a thermally activated and thereby softenable adhesive layer (2) to form a laminar structure, a linear body (7) is provided between the front substrate (1) and the rear substrate (6) framing the layer of solar cells (3), the linear body (7) comprises a thermally activated adhesive material (9), which at least one of (a) does not soften, (b) softens slower or (c) softens only at higher temperature in reference to the thermally activated adhesive layer (2).

22. A photovoltaic module, comprising a transparent front substrate (1), a rear substrate (6), a layer of solar cells (3) located therebetween, and a thermally activated and thereby softenable adhesive layer (2) to form a laminar structure, between the front substrate (1) and the rear substrate (6), a linear body (7) is arranged to frame edges of the photovoltaic module and surrounds the layer of solar cells (3), the linear body (7) comprises a thermally activated adhesive material (9), which at a temperatures used to activate the adhesive layer (2) has a higher viscosity than a viscosity of the thermally activated adhesive layer (2).

23. A photovoltaic module according to claim 21, wherein the thermally activated adhesive material (9) comprises a material of the thermally activated adhesive layer (2) with additives, which influence at least one of an adhesive effect or viscosity.

24. A photovoltaic module according to claim 21, wherein the thermally activated adhesive material (9) comprises a material of the thermally activated adhesive layer (2) with a greater layer thickness.

25. A photovoltaic module according to claim 24, wherein the layer thickness of the thermally activated adhesive material (9) is equivalent to 1.1-times to 3-times a layer thickness of the thermally activated adhesive layer (2).

26. A photovoltaic module according to claim 21, wherein the linear body (7) comprises a core (8) and a jacket layer (9) covering the core and made from the thermally activated adhesive material.

27. A photovoltaic module according to claim 21, wherein the linear body (7) comprises at least partially a thermoplastic elastomer.

28. A photovoltaic module according to claim 21, wherein the front substrate is a glass cover (1) and the rear substrate is a rear film (6).

29. A photovoltaic module according to claim 21, wherein the linear body (7) is transparent.
